(19) United States
(12) Patent Application Publication
(10) Pub. No.: US 2006/0169968 A1
(43) Pub. Date: Aug. 3, 2006

(54) Pillar phase change memory cell

(76) Inventor: Thomas Happ, Pleasantville, NY (US)

Correspondence Address: DICKE, BILLIG & CZAJA, P.L.L.C., FIFTH STREET TOWERS, 100 SOUTH FIFTH STREET, SUITE 2250, MINNEAPOLIS, MN, 55402, US

(21) Appl. No.: 11/048,186

(22) Filed: Feb. 1, 2005

(51) Int. Cl. H01L 29/02

(52) U.S. Cl. 257/2

(57) ABSTRACT

The present invention includes a phase-change memory cell device and method that includes a memory cell, a selection device, a contact, and a sublithographic pillar. The contact is coupled to the selection device. The phase-change pillar is coupled to the contact. The sublithographic pillar is coupled to the contact. The sublithographic pillar is surrounded by insulating material thereby defining sublithographic lateral dimensions of the sublithographic pillar. There is also sublithographic contact between the sublithographic pillar and the contact.

### BACKGROUND

The present invention relates to phase-change memories. In particular, a system and method are provided for a phase-change memory cell with phase-change material and a pillar having precisely controlled lateral dimensions. Phase-change materials may exhibit at least two different states. Consequently, phase-change material may be used in a memory cell to store a bit of data. The states of phase-change material may be referenced to as amorphous and crystalline states. The states may be distinguished because the amorphous state generally exhibits higher resistivity than does the crystalline state. Generally, the amorphous state involves a more disordered atomic structure, while the crystalline state is an ordered lattice.

Phase change in the phase-change materials may be induced reversible. In this way, the memory may change from the amorphous to the crystalline state, and visa versa, in response to temperature changes. The temperature changes to the phase-change material may be effectuated in a variety of ways. For example, a laser can be directed to the phase-change material, current may be driven through the phase-change material, or current or voltage can be fed through a resistive heater adjacent the phase-change material. With any of these methods, controllable heating the phase-change material causes controllable phase change within the phase-change material.

When a phase-change memory comprises a memory array having a plurality of memory cells that are made of phase-change material, the memory may be programmed to store data utilizing the memory states of the phase-change material. One way to read and write data in such a phase-change memory device is to control a current (or a voltage) that is directed through the phase-change material, or through a heater adjacent to it. If high currents or voltages are required to change the memory states of the phase-change material, the overall density of the phase-change memory is compromised. Consequently, a phase-change memory cell with a low current and/or voltage utilized to change memory states is desirable.

For these and other reasons, there is a need for the present invention.

### SUMMARY

One aspect of the present invention provides a phase-change memory cell device and method that includes a memory cell, a selection device, a contact, and a sublithographic pillar. The contact is coupled to the selection device. The sublithographic pillar is coupled to the contact. The sublithographic pillar is surrounded by insulating material thereby defining sublithographic lateral dimensions of the sublithographic pillar. There is also sublithographic contact between the sublithographic pillar and the contact.

### BRIEF DESCRIPTION OF THE DRAWINGS

The accompanying drawings are included to provide a further understanding of the present invention and are incorporated in and constitute a part of this specification. The drawings illustrate the embodiments of the present invention and together with the description serve to explain the principles of the invention. Other embodiments of the present invention and many of the intended advantages of the present invention will be readily appreciated as they become better understood by reference to the following detailed description. The elements of the drawings are not necessarily to scale relative to each other. Like reference numerals designate corresponding similar parts.

FIG. 1 illustrates a block diagram of a memory cell device.

FIGS. 2A-2C illustrate cross-sectional views through alternative phase-change memory cells in accordance with various embodiments of the present invention.

FIG. 3 illustrates a cross-sectional view through a partially fabricated phase-change memory cell in accordance with one embodiment of the present invention.

FIGS. 4A-4D illustrate a cross-sectional view through a partially fabricated phase-change memory cell in accordance with one embodiment of the present invention.

FIG. 5 illustrates a cross-sectional view through a partially fabricated phase-change memory cell in accordance with one embodiment of the present invention.

FIG. 6 illustrates a cross-sectional view through a partially fabricated phase-change memory cell in accordance with one embodiment of the present invention.

FIG. 7 illustrates a cross-sectional view through a partially fabricated phase-change memory cell in accordance with one embodiment of the present invention.

FIG. 8 illustrates a cross-sectional view through a partially fabricated phase-change memory cell in accordance with one embodiment of the present invention.

FIG. 9 illustrates a cross-sectional view through a partially fabricated phase-change memory cell in accordance with one embodiment of the present invention.

FIG. 10 illustrates a cross-sectional view through a partially fabricated phase-change memory cell in accordance with one embodiment of the present invention.

FIG. 11 illustrates a cross-sectional view through a partially fabricated phase-change memory cell in accordance with one embodiment of the present invention.

FIG. 12 illustrates a cross-sectional view through a partially fabricated heater-type phase-change memory cell in accordance with one embodiment of the present invention.

FIG. 13 illustrates a cross-sectional view through a partially fabricated heater-type phase-change memory cell in accordance with one embodiment of the present invention.

FIG. 14 illustrates a cross-sectional view through a partially fabricated heater-type phase-change memory cell in accordance with one embodiment of the present invention.

FIG. 15 illustrates a cross-sectional view through a partially fabricated heater-type phase-change memory cell in accordance with one embodiment of the present invention.

FIG. 16 illustrates a cross-sectional view through a partially fabricated heater-type phase-change memory cell in accordance with one embodiment of the present invention.

FIG. 17 illustrates a cross-sectional view through a partially fabricated heater-type phase-change memory cell in accordance with one embodiment of the present invention.

FIG. 18 illustrates a cross-sectional view through a partially fabricated heater-type phase-change memory cell in accordance with one embodiment of the present invention.

FIG. 19 illustrates a cross-sectional view through a partially fabricated heater-type phase-change memory cell in accordance with one embodiment of the present invention.

FIG. 20 illustrates a cross-sectional view through a partially fabricated heater-type phase-change memory cell in accordance with one embodiment of the present invention.

FIG. 21 illustrates a cross-sectional view through a partially fabricated heater-type phase-change memory cell in accordance with one embodiment of the present invention.

### DETAILED DESCRIPTION

In the following Detailed Description, reference is made to the accompanying drawings, which form a part hereof, and in which is shown by way of illustration specific embodiments in which the invention may be practiced. In this regard, directional terminology, such as “top,” “bottom,” “front,” “back,” “leading,” “trailing,” etc., is used with reference to the orientation of the Figure(s) being described. Because components of embodiments of the present invention can be positioned in a number of different orientations, the directional terminology is used for purposes of illustration and is in no way limiting. It is to be understood that other embodiments may be utilized and structural or logical changes may be made without departing from the scope of the present invention. The following detailed description, therefore, is not to be taken in a limiting sense, and the scope of the present invention is defined by the appended claims.

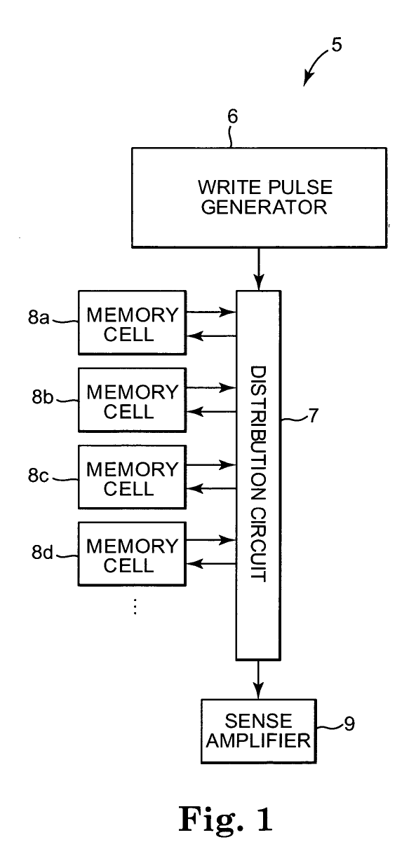

FIG. 1 illustrates a block diagram of a memory cell device 5. Memory cell device 5 includes write pulse generator 6, distribution circuit 7, memory cells 8a, 8b, 8c, and 8d and sense amplifier 9. In one embodiment, memory cells 8a-8d are phase-change memory cells that are based on amorphous to crystalline phase transition. In one embodiment, write pulse generator 6 generates current or voltage pulses that are controllable directed to memory cells 8a-8d via distribution circuit 7. In one embodiment, distribution circuit 7 is a plurality of transistors that controllable direct current or voltage pulses to the memory, and in another embodiment, is a plurality of transistors that controllable direct current or voltage pulses to heaters adjacent to the phase-change memory cells.

In one embodiment, memory cells 8a-8d are made of a phase-change material that may be changed from an amorphous state to a crystalline state or crystalline state to amorphous under influence of temperature change. The amorphous and crystalline states thereby define two-bit states for storing data within memory cell device 5. The two-bit states of memory cells 8a-8d differ significantly in their electrical resistivity. In the amorphous state, a phase-change materials will exhibit significantly higher resistivity than they will in the crystalline state. In this way, sense amplifier 9 may read the cell resistance such that the bit value assigned to a particular memory cell 8a-8d can be determined.

In order to program a memory cell 8a-8d within memory cell device 5, write pulse generator 6 generates a current or voltage pulse for heating the phase-change material in the target memory cell. In one embodiment, write pulse generator 6 generates an appropriate current or voltage pulse in distribution circuit 7 distributes the pulse to the appropriate target memory cell 8a-8d. The current or voltage pulse amplitude and duration is controlled depending on whether the memory cell is being set or reset. Generally, a “set” operation of a memory cell is heating the phase-change material of the target memory cell above its crystalline temperature (but below its melting temperature) long enough to achieve the crystalline state. Generally, a “reset” operation of a memory cell is quickly heating the phase-change material of the target memory cell above its melting temperature, and then quickly quench cooling the material, thereby achieving the amorphous state.

In order to reach the target melting temperature required to reset a memory cell, a relatively high amplitude current or voltage pulse of short direction is sent from write pulse generator 6 to the target memory cell 8a-8d causing the phase-change material to melt and to amorphize during the subsequent quench cooling. In accordance with the present invention, however, a phase-change memory cell using a lower reset current than conventional phase-change memory cells is achieved. In this way, a relatively high density and low cost phase-change memory may be achieved by using a smaller feature size (width) of the selection device such as a transistor or diode.

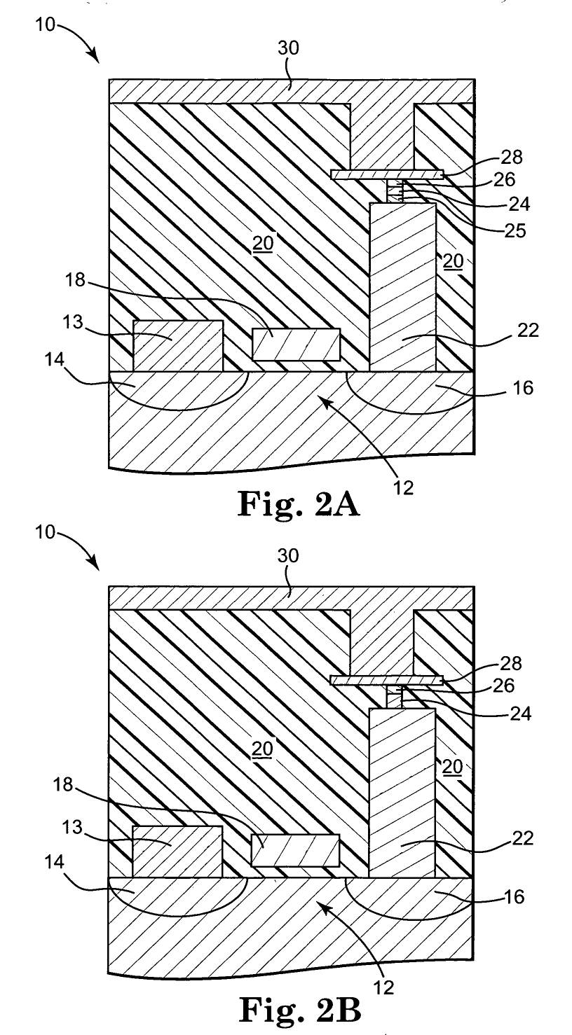

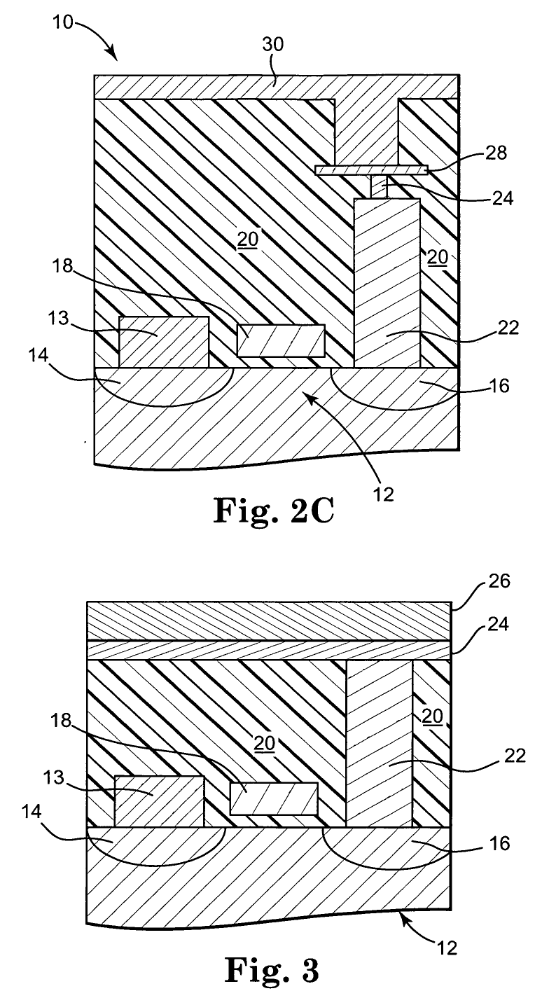

FIGS. 2A-2C illustrates a cross-section view through an exemplary phase-change memory cell 10 in accordance with various embodiments of the present invention. Phase-change memory cell 10 includes selection device 12, plate line 13, insulator material 20, contact plug 22, phase-change material 24, contact pad 28 and bit line 30.

Selection device 12 may be an active device such as a transistor or diode. In one embodiment, selection device 12 is a field effect transistor having a source 14, a drain 16, and a control gate 18. Selection device 12 is used to control the application of current or voltage from plate line 13 to contact plug 22, and thus to phase-change material 24, in order to set and reset phase-change material 24. Selection device 12 is formed using lithographic techniques.

In each of the embodiments illustrated in FIGS. 2A-2C, phase-change memory cell 10 utilizes phase-change material 24 that is in a pillar formed between contact pad 28 and contact plug 22. In each case, the pillar is formed using techniques, as will be described more fully below, to have sublithographic lateral dimensions. In this way, only a small amount of current or voltage is needed for a reset operation. Consequently, minimum feature size is allowed in order to obtain maximum density for phase-change memory cell 10.

In the embodiment illustrated in FIG. 2A, phase-change material 24 is between top and bottom electrodes 25 and 26 in the pillar. In the embodiment illustrated in FIG. 2B, phase-change material 24 is under top electrode 26 in the pillar. In the embodiment illustrated in FIG. 2C, phase-change material 24 is the only material in the pillar. One skilled in the art will see other alternatives are available, including having phase-change material 24 over bottom electrode 25 in the pillar. By forming the pillar in each case with sublithographic dimensions, decreased power may be utilized.

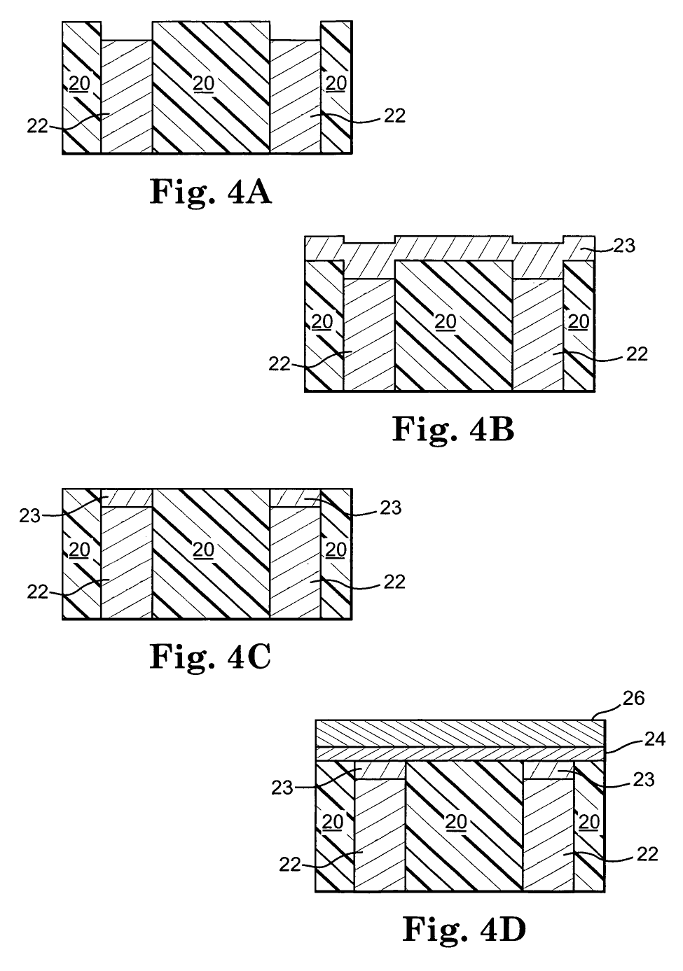

FIGS. 3-10 illustrate cross-sectional views through phase-change memory cell 10 at various stages of fabrication. The fabrication process for each of the embodiments of phase-change memory cell 10 illustrated in FIGS. 2A-2C is highly similar. Consequently, to simplify the description, the process will be described for the specific embodiment illustrated in FIG. 2B (that having phase-change material 24 under top electrode 26 in the pillar), but one skilled in the art will understand how other alternative embodiments may be similarly fabricated. In addition, although formation of two memory cells are illustrated in the Figures, one skilled in the art will recognize that a typical fabrication process will involve fabrication of multiple memory cells at one time. It is assumed that each of these memory cells include a phase change pillar and a selection device. Only one of the memory cells will be described in the following in order to simplify the illustration description, and for FIGS. 4-21, the selection device and associated plate line will not be illustrated.

In FIG. 3, selection device 12 is illustrated having been formed by lithographic techniques. Contact plug 22 surrounded by insulator material 20 are then formed over selection device 12. Next, phase-change material 24 is deposited as a layer. In one embodiment, phase-change material 24 is deposited in a planar film using known deposition methods such as sputtering.

In one embodiment, typical thickness of phase-change material 24 may be on the order of 30-100 nanometers. In other embodiments, phase-change material 24 may be on the order of 50-70 nanometers. Phase-change material 24 may be made up of a variety of materials in accordance with the present invention. Generally, chalcogenide alloys that contain one or more elements from Column IV of the periodic table are useful as such materials. In one embodiment, phase-change material 24 of memory cell 10 is made up of a chalcogenide compound material, such as GeSbTe or AgInSbTe.

After the deposition of phase-change material 24, top electrode 26 is deposited over phase-change material 24, as illustrated in FIG. 3. Top electrode 26 is also deposited as a layer using one of a variety of known techniques for depositing metals. In one embodiment, top electrode 26 is a metal nitride material, such as titanium nitride, titanium silicon nitride, titanium aluminum nitride, or tungsten nitride, or in another embodiment it may be a titanium tungsten material. As indicated previously, FIG. 3 illustrates a step for forming the specific embodiment illustrated in FIG. 2B. For the embodiment illustrated in FIG. 2A, a layer of bottom electrode 25 would have been deposited before the layer of phase-change material, and for the embodiment illustrated in FIG. 2C, no electrode layers would be formed. Each of the electrodes may be made of the above-listed materials.

FIGS. 4A-4D illustrate an alternative embodiment to that illustrated in FIG. 3, wherein lower electrode 23 is fabricated adjacent contact plug 22 before phase-change material. 24 and top electrode 26 are deposited. In this alternative embodiment, contact plug 22 is first back etched to form a recess as illustrated in FIG. 4A. Next, a layer of lower electrode 23 is deposited over the stack, including in the via formed by the back etch of the previous step. This is illustrated in FIG. 4B. A chemical/mechanical polish (“CMP”) is then used to planarize and smooth the top surface of the stack, as illustrated in FIG. 4C. Finally, deposition of phase-change material 24 and top electrode 26 is done over the planarized stack, as illustrated in FIG. 4D. Bottom electrode 25, may be deposited in the stack over the lower electrodes 23. Lower electrode 23 may be useful for providing a diffusion barrier to phase-change material 24 in some applications.

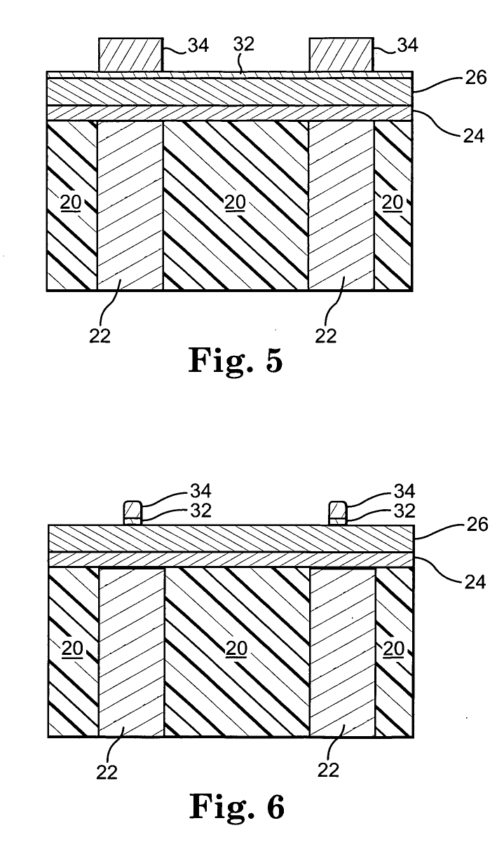

FIG. 5 illustrates a subsequent step in the fabrication process of phase-change memory cell 10. Here, a critical lithography process is used to form photoresist patches 34. Anti-reflective coating (ARC) 32 is first formed over top electrode 26 and photoresist layer 34 formed over ARC 32. In one embodiment, the thickness for photoresist layer 34 is approximately 300 nanometers while the thickness of ARC layer 32 is approximately 90 nanometers. In one embodiment, ARC 32 is an inorganic anti-reflective coating material, while in other embodiments it may be an organic anti-reflective coating material.

Photoresist 34 first goes through the lithography wherein it is exposed through a mask and then non-reacted portions are washed away leaving the resist patches 34, as illustrated in FIG. 5. Next, the resist patches (photoresist 34) are laterally trimmed with a plasma resist trimming step. With this step, the resist patch is dry etched in an oxygen and fluorocarbon and/or hydrogen bromide containing plasma, thus forming a sublithographic resist pillar. In one embodiment, top resist erosion in the etching process is balanced by polymer formation such that the lateral critical dimension (in the left and right directions as depicted in FIG. 6) is reduced without drastic reductions in thickness (up and down as depicted in FIG. 6). In one embodiment, this trim step can be used to simultaneously open and trim the ARC 32. In one embodiment, a typical diameter of ARC 32 and photoresist 34 resist pillar is 30-50 nanometers after this processing step.

In the case where an inorganic ARC 32 is used, another dry etch step is used to open the ARC 32. This can be advantageously utilized as a hard mask during the subsequent resist pillar etching processes.

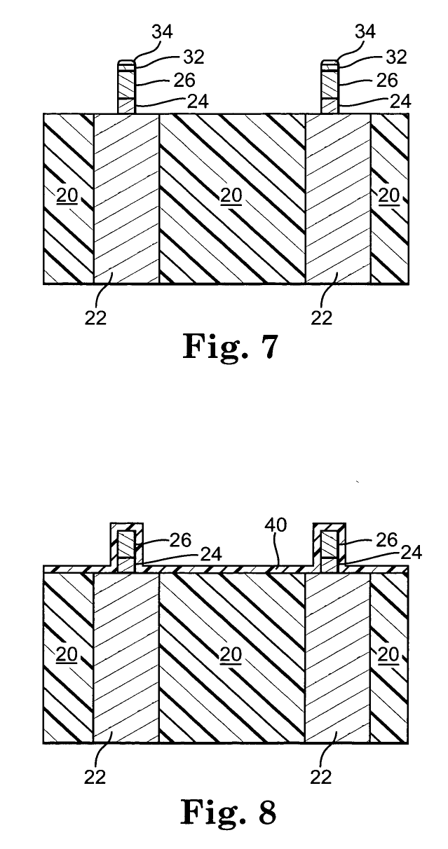

FIG. 7 illustrates a subsequent step in the fabrication process of phase-change memory cell 10. Here, the resist pillar (consisting of resist 34 and ARC 32) formed in the previous step is used as an etch mask during a dry etch to form a sublithographic phase-change pillar, which in one embodiment, is made up of phase-change material 24 and top electrode 26. As indicated previously, in other embodiments, the phase-change pillar may consist of just phase-change material 24, in others it may consist of bottom electrode 25, phase-change material 24, and top electrode 26, and in other embodiments it may consist of bottom electrode 25 and phase-change material 24. In any event, the shape of the resist pillar, consisting of the ARC 32 and photoresist 34, is transferred to the phase-change pillar. The original thickness of the resist pillar is chosen so that after this etch step, a finite amount remains on the structure to preserve its shape.

As is evident, the lateral dimensions of the phase-change pillar of phase-change material 24 and top electrode 26, that is, the left and right directions as depicted in FIG. 7, are precisely preserved in the etching process. In this way, the contact surface between the sublithographic phase-change pillar and contact plug 22 can be minimized and tightly controlled. In one embodiment, the lateral sublithographic dimensions of the phase-change pillar of phase-change material 24 and top electrode 26 is controlled to be 30-50 nanometers. This sublithographic dimension control, and corresponding minimized surface contact with adjacent surfaces, effectively lowers the reset current that will be required in phase-change memory cell 10. This is turn allows high-density cell fabrication.

FIG. 8 is a cross-section illustrating a further step in the fabrication process of phase-change memory cell 10. Here, the remaining portions of the resist pillar of ARC 32 and photoresist 34 are stripped away and additional barrier material 40 is deposited over the stack surface. In one embodiment, ARC 32 and photoresist 34 are removed using oxygen and/or fluorine containing plasma to burn away the resist. In one embodiment, barrier material 40 is a silicon nitride material that provides encapsulation of the phase-change pillar and helps isolate the phase-change pillar from subsequent processing.

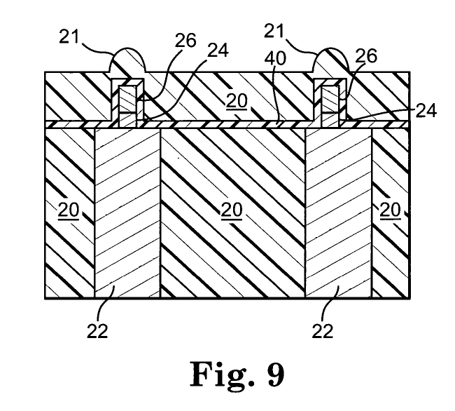

FIG. 9 is a cross-section illustrating a further step in the fabrication process of phase-change memory cell 10. Here, insulator material 20 is deposited over the barrier material 40. In one embodiment, insulator material 20 is a silicon dioxide and in another, is a plasma oxide. Because of the pillar-shape of the phase-change pillar of phase-change material 24 and top electrode 26, bumps 21 may form in the insulator material 20 as it is deposited over the top of the stack. Consequently, it may be necessary to remove the bumps using CMP process.

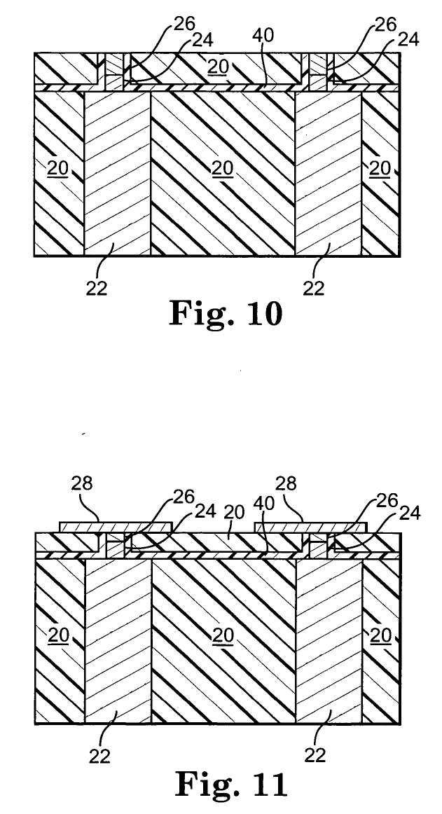

FIG. 10 illustrates a cross-section of a step in the fabrication process of phase-change memory cell 10 where such a CMP process has been used to planarize the top of the stack. The end point of the CMP step is selected in such a way that some of electrode material 26 remains and phase-change material 24 is not exposed. Of course, where phase-change pillar consists of only phase-change material 24, it will be exposed in this step.

FIG. 11 is a cross-section illustrating the next step in the process of fabricating phase-change memory cell 10. Here, contact pad 28 is fabricated over top electrode 26. Since the phase-change pillar is quite narrow, contact pad 28 may be useful to land and stop the contact etch needed to form the following contact to the upper metallization layer. In one embodiment, contact pad 28 may be formed by blank metal deposition, lithography and an etch process. Next, a further contact, such as bit line 30 (illustrated in FIG. 2) may be formed by standard metallization process using dual damascene and plug formation. In one embodiment, contact pad 28 may be a titanium nitride and bit line 30 may be an aluminum or copper material with the required barrier/liner materials.

Using this process to form the sublithography phase-change pillar of material 24 and top electrode 26 creates a very small contact area between phase-change material 24 and both top electrode 26 and contact plug 22. In this way, reset current in phase-change memory cell 10 may be significantly lower than previous applications thereby creating the opportunity to increase cell density. Using the critical lithography process to form the resist pillar, followed by the plasma resist trimming step, and then forming the sublithographic phase-change pillar from the resist pillar, allows for lateral dimensions of the phase-change pillar that may be very tightly controlled. In addition, by using this process, the interfaces between electrodes and phase-change material 24 can be excellently controlled. Such interfaces may either be meticulously cleaned after a polish or may be deposited without the need of polishing or etching at the interface. For example, where bottom electrode 25, phase-change material 24 and top electrode 26 are deposited all in-situ, vacuum does not need to be broken thereby decreasing the likelihood of contamination. This can provide improved cycle life time of the phase-change memory cell 10.

Phase-change memory cell 10 illustrated in FIG. 2 is an active-in-via phase-change memory cell. In other words, current or voltage is selectively directed directly through phase-change material 24 in order to heat the material to perform set and reset operations.

In an alternative embodiment of the present invention, a phase-change memory cell may be a heater-cell. In this way, rather than forming phase-change material 24 in the pillar-like shape illustrated in FIG. 2, a heater pillar is formed in the place of phase-change material 24. In the same way described above for the formation of phase-change pillar, such a heater pillar will have lateral dimensions (again, those in the left and right direction as illustrated in FIG. 2) that are precisely controlled by using the critical lithography process to form the resist pillar, followed by the plasma resist trimming step, and then forming the sublithographic heater pillar from the resist pillar. The lateral dimensions of the heater pillar would still be very tightly controlled as above.

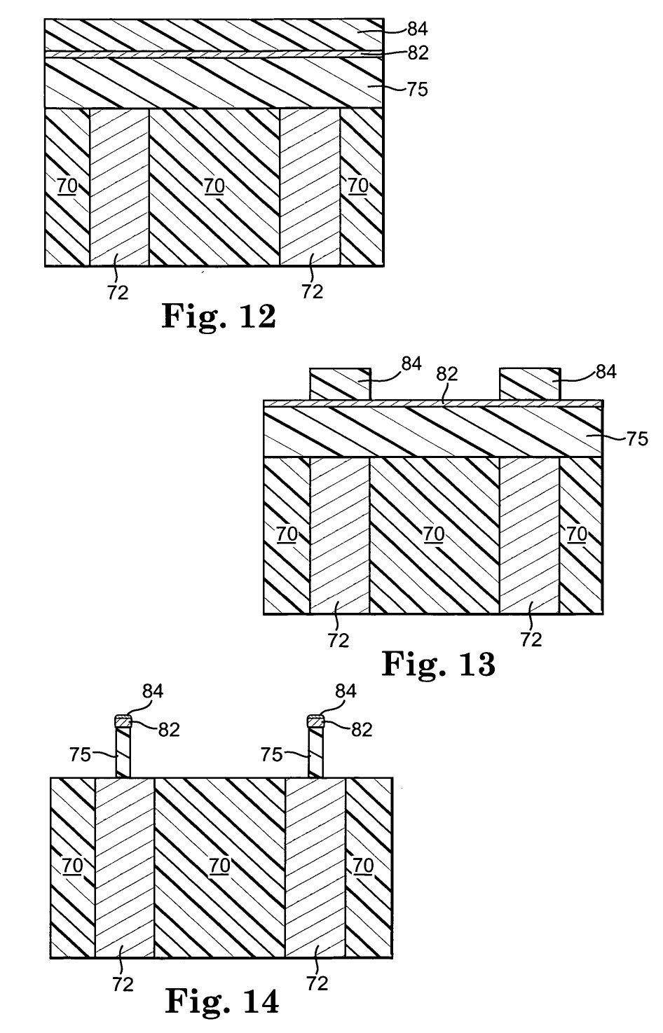

FIGS. 12-21 illustrate, in cross-section, various step in the fabrication process of a heater-type phase-change memory cell 60. Analogous to phase-change memory cell 10 above, heater-type phase-change memory cell 60 also includes a selection device (not illustrated in the Figures), insulator material 70, contact plug 72, heater material 75, phase-change material 74 (illustrated in FIG. 21), contact pad 76. It also may include a bit line (not illustrated in the Figures) that couples to contact pad 76. Although highly similar to that above for phase-change memory cell 10, the fabrication of heater-type phase-change memory cell 60 is briefly described below.

In FIG. 12, heater material 75 is illustrated deposited over the combination of contact plug 72 and insulator material 70. Anti-reflective coating (ARC) 82 is then deposited, followed by photoresist layer 84. A critical lithography process is then used to form photoresist patches 84 illustrated in FIG. 13. A resist pillar is then formed with ARC 72 and photoresist 74 and these resist pillars are laterally trimmed with a plasma resist trimming/ARC open step.

FIG. 14 illustrates a subsequent step in the fabrication process of heater-type phase-change memory cell 60. Here, the resist pillar formed in the previous step is used as an etch mask during a dry etch to form a sublithographic heater pillar, which is made up of heater material 75. The shape of the resist pillar, consisting of the ARC 82 and photoresist 84, is transferred to the heater pillar.

As is evident, the lateral dimensions of the heater pillar, that is, the left and right directions as depicted in FIG. 14, are precisely preserved in the etching process. In this way, the contact surface between the sublithographic heater pillar and adjacent contact plug 72 can be minimized and tightly controlled.

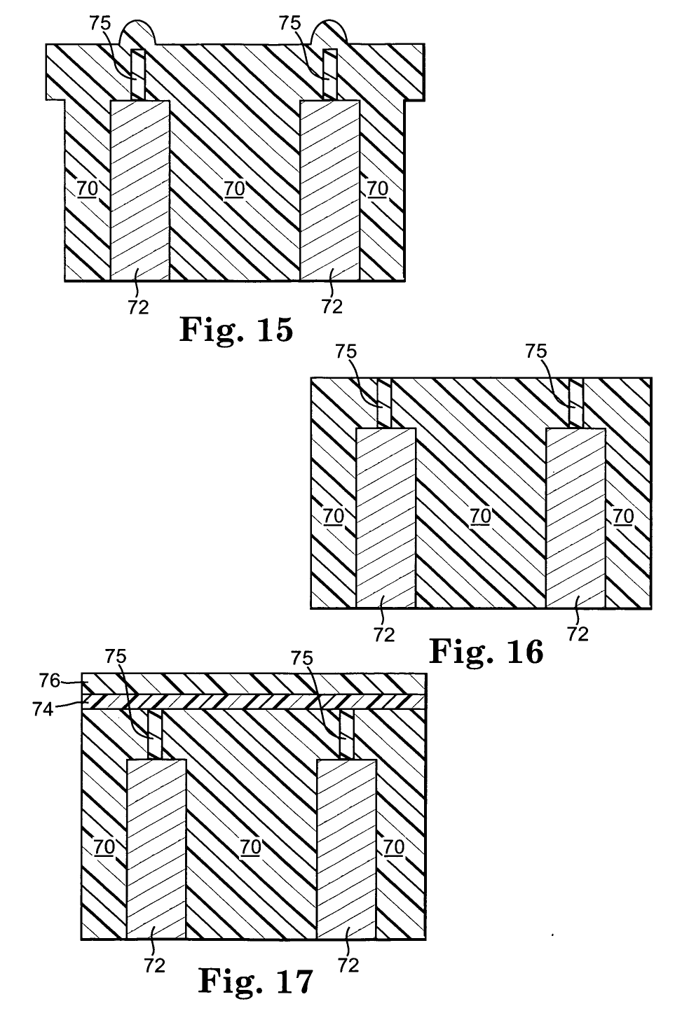

FIG. 15 is a cross-section illustrating a further step in the fabrication process of heater-type phase-change memory cell 60. Here, the remaining portions of the resist pillar of ARC 82 and photoresist 84 are stripped away and additional insulator material 70 is deposited over the stack surface. Bumps 71 will form over the heater pillar 75. Consequently, it may be necessary to remove the bumps using CMP process, resulting in the illustration of FIG. 16 after planarization.

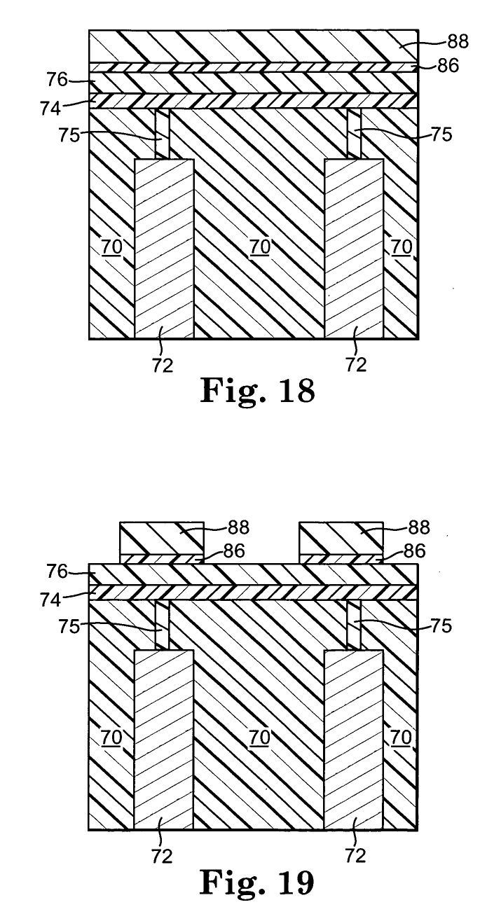

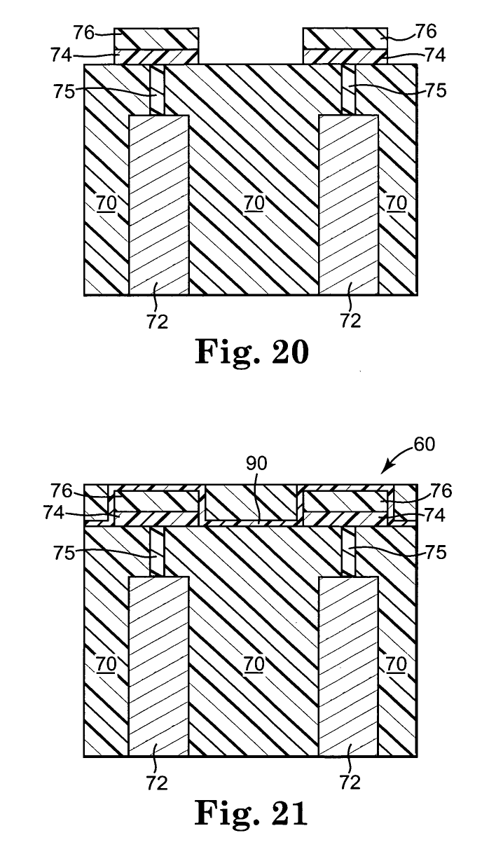

Next, a layer of phase-change material 74 is deposited followed by a layer of top electrode 76, as illustrated in FIG. 17. Then, layers of ARC 86 and photoresist 88 are deposited over these layers are illustrated in FIG. 18. Similar to previously-described processing, a lithography process is then used to form photoresist patches 86 and 88 illustrated in FIG. 19, and then these resist patches are used to mask phase-change material 74 and top electrode 76 during subsequent etching, such that the stack illustrated in FIG. 20 results.

In addition, in one embodiment a barrier material 90 is deposited over the stack illustrated in FIG. 20, and then additional insulator material 70 is added to produce heater-type phase-change memory cell 60 illustrated in FIG. 21. The barrier material 90 may be a silicon nitride material that provides encapsulation of the phase-change material 74 and helps isolate the phase-change material 74 from subsequent processing.

An alternative embodiment like heater-type phase-change memory cell 60 still has the advantage of a precisely controlled interface between the heater 75 and phase-change material 74, as well as between the heater 75 and contact plug 72. In this way, such tightly controlled dimensions allow for minimal current use to perform a reset in the memory cell. Consequently, a phase-change memory cell 60 using a heater may also be used to increase cell density.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. A phase-change memory cell device comprising:
a selection device;
a contact coupled to the selection device; and
an etched sublithographic pillar coupled to the contact, wherein the sublithographic pillar is surrounded by insulating material thereby defining sublithographic lateral dimensions of the sublithographic pillar and such that there is sublithographic contact between the sublithographic pillar and the contact.

2. The phase-change memory cell device of claim 1, wherein the sublithographic pillar further comprises a phase-change material within the pillar.

3. The phase-change memory cell device of claim 2, wherein the sublithographic pillar further comprises an electrode adjacent the phase-change material within the pillar.

4. The phase-change memory cell device of claim 3, wherein the sublithographic pillar further comprises top and bottom electrodes above and below the phase-change material within the pillar.

5. The phase-change memory cell device of claim 1, wherein the sublithographic pillar further comprises heater material within the pillar and wherein the phase-change memory cell further comprises phase-change material adjacent the pillar such that there is sublithographic contact between the pillar and the phase-change material.

6. The memory cell device of claim 1, further including an etched region of the contact in which a lower electrode is formed such that is between the sublithographic pillar and the contact.

7. A memory device comprising:
a write pulse generator for generating a write pulse;
a sense amplifier for sensing a read signal;
a distribution circuit; and
a plurality of memory cells each capable of defining at least a first and a second state, each memory cell further comprising a phase-change pillar having phase change material, the phase change pillar having sublithographic lateral dimensions that are formed by etching a resist pillar mask.

8. The memory device of claim 7, wherein the resist pillar mask is formed by a lithography process and its dimensions are then transferred to the phase-change pillar by a plasma etch.

9. The memory device of claim 8, wherein the resist pillar mask comprises a photoresist material and an organic antireflective coating material.

10. The memory device of claim 8, wherein the resist pillar mask comprises a photoresist material and an inorganic antireflective coating material that is used as a hard mask.

11. The memory device of claim 7, wherein the sublithographic lateral dimensions of the phase-change pillar are such that the write pulse required to change phase-change memory cells from the first state to the second state is minimized.

12. A memory cell device comprising:
a transistor having first and second conductive terminals and a control terminal;
a first contact coupled to the first conductive terminal;
phase-change material adjacent the first contact;
a second contact adjacent the phase change material; and
a bit line coupled to the second contact;
wherein the phase-change material has sublithographic lateral dimensions, thereby minimizing the surface contact between the phase-change material and the adjacent contacts.

13. The memory cell device of claim 12, wherein the sub-lithographic lateral dimensions of the phase-change pillar is 30-50 nanometers.

14. The memory cell device of claim 12 further comprising a first electrode between the phase-change material and the first contact, wherein the first electrode has lateral dimensions between 2 and 150 nanometers, and further comprising a second electrode between the phase-change material and the second contact, wherein the second electrode has lateral dimensions between 10 and 200 nanometers.

15. The memory cell device of claim 12, further including a barrier layer over the phase-change material.

16. The memory cell device of claim 15, wherein the barrier layer is a silicon nitride material that provides a barrier between the phase-change material and other materials.

17. A memory cell device comprising:
a selection device;
a contact coupled to the selection device;
a heater pillar coupled to the contact, the heater pillar having sublithographic lateral dimensions; and
phase-change material adjacent the heater, such that there is sublithographic contact between the heater pillar and the phase change material.

18. The memory device of claim 17, wherein the sublithographic lateral dimensions of the heater pillar are formed by etching a resist pillar mask, which is formed by a lithography process followed by a plasma etch step.

19. A method of fabricating a memory cell device, the method comprising:
fabricating a first contact of the memory cell device;
depositing a layer of phase-change material over the first contact;
depositing a resist layer over the layer of phase-change material;
using a lithography process to form a resist mask over the phase-change material;
etching the resist mask to form a resist pillar; and
etching the resist pillar and phase-change material to form a phase-change pillar.

20. The method of claim 19, wherein etching the resist mask further includes trimming the resist mask with plasma before etching resist pillar and phase-change material to form the phase-change pillar with sublithographic dimensions.

21. The method of claim 19 further comprising first etching the first contact to form a recessed region and depositing and planarizing a lower electrode in the recessed region before depositing the layer of phase-change material.

22. The method of claim 19 further comprising depositing a barrier layer over the phase-change pillar.

23. The method of claim 19 further comprising depositing an electrode layer over the phase-change material such that the etching the resist pillar and phase-change material also etches the electrode layer in such a way that the phase-change pillar comprises phase-change material and an electrode.

24. The method of claim 19 further comprising coupling the phase-change pillar to a bit line.

25. A method of fabricating a memory cell device, the method comprising:
fabricating a first contact of the memory cell device;
depositing a layer of phase-change material over the first contact;
means for forming a resist pillar over the layer of phase-change material; and
means for forming a phase-change pillar using the resist pillar.

26. A method of fabricating a memory cell device, the method comprising:
providing a selection device for controlling a reset signal to the memory cell device;
fabricating a first contact adjacent the selection device;
depositing a layer of phase-change material adjacent the first contact;
depositing a resist mask over the layer of phase-change material;
etching the resist mask to form a resist pillar having narrow lateral dimensions over the phase-change material;
etching the resist pillar and phase-change material such that the narrow lateral dimensions of the resist pillar are transferred to the phase-change material, thereby forming a phase-change pillar; and
fabricating a second contact adjacent phase-change pillar such that the selection device may direct the reset signal through the phase-change pillar via the first and second contacts.

27. The method of claim 26, wherein etching the resist mask further includes trimming the resist mask with plasma resist.
